(19) United States
(12) Patent Application Publication
(10) Pub. No.: US 2006/0228889 A1
(43) Pub. Date: Oct. 12, 2006

(54) Methods of removing resist from substrates in resist stripping chambers

(76) Inventors: Erik A. Edelberg, Castro Valley, CA (US); Gladys S. Lo, Fremont, CA (US); Jack K. Kuo, Pleasanton, CA (US)

Correspondence Address: BUCHANAN, INGERSOLL & ROONEY PC, POST OFFICE BOX 1404, ALEXANDRIA, VA, 22313-1404, US

(21) Appl. No.: 11/094,689

(22) Filed: Mar. 31, 2005

(51) Int. Cl. C23F 1/00; H01L 21/302

(52) U.S. Cl. 438/689; 216/67

(57) ABSTRACT

Methods for stripping resist from a semiconductor substrate in a resist stripping chamber are provided. The methods include producing a remote plasma containing reactive species and cooling the reactive species inside the chamber prior to removing the resist with the reactive species. The reactive species can be cooled by being passed through a thermally-conductive gas distribution member. By cooling the reactive species, damage to a low-k dielectric material on the substrate can be avoided.

### BACKGROUND

Semiconductor substrate materials, such as silicon wafers, are processed by techniques including deposition processes, etching processes and resist stripping processes. Semiconductor integrated circuit (IC) processes include forming devices on substrates. During these processes, conductive and insulating material layers are deposited on the substrates. Resist can be applied as a mask and patterned to protect portions of the underlying material where etching is not desired. After the etch process has been completed, the resist is removed from the structure by a stripping technique.

### SUMMARY

A preferred embodiment of a method of stripping resist from a semiconductor substrate in a resist stripping chamber comprises supporting a semiconductor substrate in a resist stripping chamber. The semiconductor substrate includes a low-k dielectric material and a resist layer overlying the low-k dielectric material. The low-k dielectric material has a thermal degradation temperature. A remote plasma is produced from a process gas, and a gas containing reactive species at a temperature above the thermal degradation temperature of the low-k dielectric material is supplied therefrom into the resist stripping chamber. The reactive species are cooled in the plasma stripping chamber to a temperature below the thermal degradation temperature of the dielectric material. The resist layer is stripped from the semiconductor substrate with the cooled reactive species, while the semiconductor substrate is maintained at a temperature that does not exceed the thermal degradation temperature of the low-k dielectric material.

In a preferred embodiment, the low-k dielectric material is an organic low-k dielectric material.

In a preferred embodiment, the reactive species are cooled by passing the reactive species through flow passages of a thermally-conductive gas distribution member facing the semiconductor substrate.

In a preferred embodiment, the semiconductor substrate is heated by a substrate support set to a temperature below the thermal degradation temperature of a low-k dielectric material of a semiconductor substrate supported on the substrate support.

### BRIEF DESCRIPTION OF THE DRAWINGS

FIG. 1 depicts an exemplary embodiment of a resist stripping chamber that can be used to practice embodiments of the methods of removing resist from substrates.

FIG. 2 illustrates a preferred embodiment of a baffle used in the resist stripping chamber.

FIG. 3 illustrates a liner positioned on the baffle shown in FIG. 2.

FIG. 4 illustrates an embodiment of a semiconductor substrate comprising a low-k dielectric material layer and an overlying resist layer.

FIG. 5 illustrates the substrate shown in FIG. 4 after a resist has been stripped from the substrate.

FIG. 6 shows the relationship between on-wafer (surface) temperature at different locations on a wafer surface when a thermally-conductive baffle is not used in the resist stripping chamber.

FIG. 7 shows the relationship between on-wafer temperature at different locations on a wafer surface when a thermally-conductive baffle is used in the resist stripping chamber.

### DETAILED DESCRIPTION

Resist stripping chambers are used in semiconductor device manufacturing processes to remove resist (which is also referred to as “photoresist”) used as a “soft mask” for semiconductor structures. Typically, resist is removed from underlying layers of the semiconductor structure after one or more of the layers have been etched to form features in those layers. Resist stripping can be performed numerous times during manufacturing of devices.

One stripping technique that can be performed in resist stripping chambers to remove resist from semiconductor structures is dry stripping, which is also referred to as “ashing.” Dry stripping uses plasma dry etching techniques.

Remote plasma sources can be used to produce remote plasma for the dry stripping of resist masks in semiconductor processing. Conventional plasma sources produce ionized and reactive neutral species and ultraviolet (UV) photons in the same processing chamber as the process substrate. However, ion bombardment can cause the degradation and loss of integrity of certain materials, such as low-k dielectric materials. In contrast, in remote plasma source systems, the process substrate is located “downstream” from the remote plasma source, and the remote plasma source can deliver a gas that contains only long-lived reactive species to contribute to the etch reaction to remove the resist layer in the stripping chamber.

However, undesirable substrate heating can occur with remote plasma sources when high-power plasma processing techniques are used for resist stripping processes. The application of high power, e.g., by using microwave energy, to process gases used to produce remote plasma for stripping results in the reactive species being heated to a high temperature. In such processes, hot reactive species can transfer a sufficient amount of heat to the process substrate to cause the substrate to reach an undesirably high temperature.

However, the etch rates of materials used to form the semiconductor substrate, the etch selectivity of the materials, and properties of the materials can be strongly dependent on the maximum temperature reached by the process substrate during plasma processing. For example, if the substrate becomes too hot, uncontrolled process conditions can develop on the substrate surface, resulting in undesirable etch reactions and damage to temperature-sensitive materials.

Low-k dielectric materials can be used in multi-level interconnection applications. For example, in order to reduce RC delays of multi-level wiring that connects individual devices of silicon integrated circuits, multi-level metallization structures including low-k dielectric materials can be used. Low-k dielectric materials have a dielectric constant of less than about 4. Low-k dielectric materials can be organic, inorganic (i.e., related to SiO₂) or hybrid materials (which contain both carbon and silicon groups).

For such semiconductor structures, following etching of the low-k dielectric material, the resist layer is stripped in a resist stripping chamber. However, for such resist stripping processes, there are challenges in successfully removing the resist layer without damaging the low-k dielectric material film, i.e., without increasing the k value of the low-k dielectric material or degrading film integrity. For example, low-k dielectric materials can be damaged by oxidation when oxygen plasmas are used for resist stripping processes. During resist stripping processes, oxygen can diffuse into low-k dielectric materials. Elevated temperatures increase the rate of oxygen diffusion into these materials. As a result, the k value of low-k dielectric materials can increase and film integrity can be degraded, thereby eliminating advantages of using the low-k dielectric material. As a result, it is desirable to control the substrate temperature to minimize such problems resulting from excessive diffusion of oxygen.

Accordingly, during resist stripping processes, it is desirable to maintain the substrate temperature below a certain maximum temperature in order to maintain a desired etch selectivity, as well as to maintain desired properties of layers of the substrate. It has been determined, however, that the constituents of the remote plasma can be at a sufficiently high temperature when introduced into the stripping chamber such that the reactive species that reach the substrate heat the substrate to a temperature above the maximum temperature. More particularly, if the temperature of the reactive species distributed over the processed surface of the substrate exceeds the maximum temperature, the reactive species can heat the substrate to a temperature above the maximum temperature. As a result, one or more layers of the substrate can be damaged and the etch selectivity of the process can be reduced to an unacceptable value.

In photoresist stripping chambers, substrates can be supported on a temperature-controlled platen. Such platens are adapted to maintain the substrate at a desired temperature when the substrate is supported on the platen and the chamber pressure is sufficiently high to achieve good thermal conductance between the substrate and the platen. However, during resist stripping processes, these systems operate at vacuum conditions (˜1 Torr or less) at which heat transfer between the substrate and platen is typically poor. Consequently, even if the platen temperature is set below the maximum temperature when the substrate is supported on the platen, such systems are unable to satisfactorily control the substrate temperature during resist stripping at the lower chamber pressure.

It has been determined, however, that reactive species produced by a remote plasma source can be cooled inside the resist stripping chamber to preferably minimize heating of substrates being processed in the chamber. Preferably, the reactive species are cooled by a thermally-conductive gas distribution member. The gas distribution member is adapted to cool the reactive species to a sufficiently low temperature such that the reactive species do not cause the substrate temperature to exceed a preferred maximum temperature during the resist stripping process. The preferred maximum temperature is dependent on the compositions of the layers of the process substrate. The gas distribution member can be, for example, a gas distribution plate or baffle having gas flow passages.

In an embodiment, the gas distribution member is a baffle of aluminum or other suitable thermally conductive material that can be used in the resist stripping chamber. In a preferred embodiment, the baffle is of aluminum or an aluminum alloy (which are both encompassed by the term “aluminum” as used herein). For example, the aluminum alloy can be 6061 aluminum.

The aluminum material of the baffle preferably has an outer aluminum oxide layer that can provide resistance to oxidation and/or erosion by etch process gases, including fluorinated gases. The aluminum oxide layer is preferably provided on all surfaces of the baffle that are exposed to the reactive species. The aluminum oxide layer preferably has a thickness of from about 50 angstroms to about 300 angstroms, more preferably from about 50 angstroms to about 100 angstroms. The outer aluminum oxide layer preferably has a density of at least about 90%, more preferably at least about 95%, of the theoretical density of aluminum oxide.

In an embodiment, the gas distribution member, such as a baffle, can include a thin protective outer coating of a suitable material, such as quartz (i.e., SiO₂). The coating preferably has sufficiently low thermal mass such that it does not significantly reduce the composite heat transfer properties of the gas distribution member. The coating is preferably provided on all surfaces of the gas distribution member that are exposed to the reactive species.

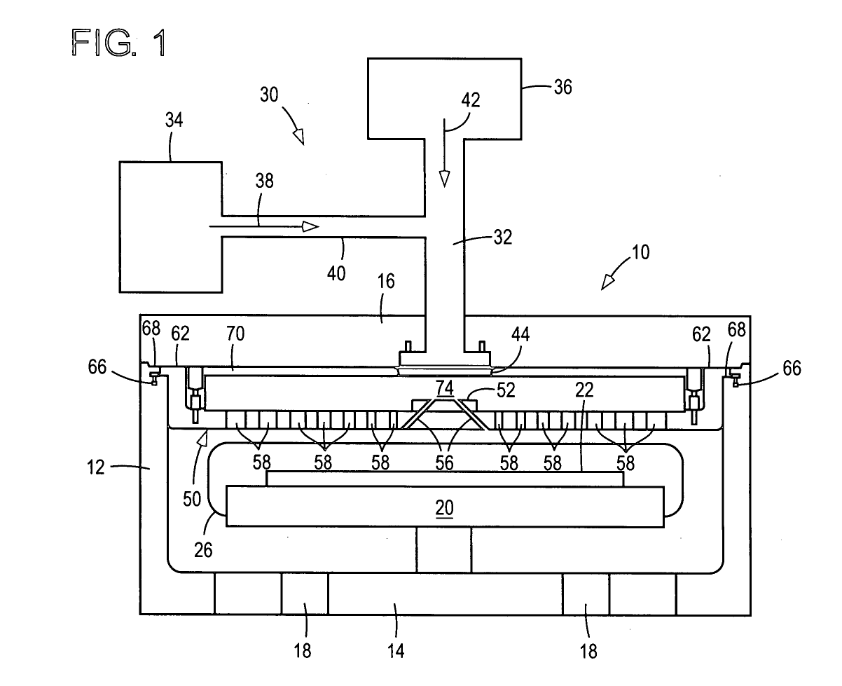

FIG. 1 depicts an exemplary embodiment of a resist stripping chamber 10 including a gas distribution member, i.e., a baffle 50. The resist stripping chamber 10 can be used for performing embodiments of the methods of stripping resist from substrates. The resist stripping chamber 10 includes a side wall 12, a bottom wall 14 and a cover 16. The walls 12,14 and the cover 16 can be of any suitable metallic, ceramic and/or polymeric material. The cover 16 is preferably pivotably attached to the side wall 12. The resist stripping chamber 10 includes vacuum ports 18 in the bottom wall 14.

The resist stripping chamber 10 also includes a substrate support 20 adapted to support a semiconductor substrate 22, such as a wafer, during resist stripping process. The substrate 22 includes a resist that provides a masking layer for protecting underlying layers of the substrate 22 during the resist stripping process. The underlying layers can be of conductive, insulative and/or semiconductive materials.

The substrate support 20 preferably includes a heater adapted to heat the upper surface 23 of the substrate support on which the substrate 22 is supported. The temperature to which the substrate is heated during the resist stripping process depends on the compositions of the particular layers of the substrate 22. The heater is preferably adapted to heat the substrate 22 to a temperature that is no higher than a maximum temperature that the substrate can be exposed to without damaging one or more layers of the substrate, or reducing the etch selectivity of the process to an unacceptable value. For example, for a maximum substrate temperature of about 100° C., the heater preferably can heat the substrate to a temperature of less than about 100° C., such as from about 25° C. to about 95° C.

The substrate 22 can be introduced into, and removed from, the resist stripping chamber 10 through a substrate entry port 26 provided in the sidewall 12. For example, the substrate 22 can be transferred into the interior of the resist stripping chamber 10 from an etching chamber connected by a transfer chamber to the resist stripping chamber.

In the embodiment, a remote plasma source 30 is arranged to produce remote plasma and supply a gas containing reactive species into the interior of the resist stripping chamber 10 through a passage 32 connected to the resist stripping chamber 10. The reactive species are effective to remove resist from the substrate 22 supported on the substrate support 20. The illustrated embodiment of the plasma source 30 includes a remote energy source 34 and a stripping gas source 36. The energy source 34 can be any suitable source, and is preferably a microwave generator. Exemplary apparatuses including a microwave generator are available from Lam Research Corporation located in Fremont, Calif. A suitable resist stripping chamber is the Model No. 2300 available from Lam Research Corporation. In a preferred embodiment, the microwave generator supplies a power level in the range of about 1000 W to about 3000 W, more preferably in the range of about 2000 W to about 2500 W. Generally, increasing the applied power level increases the amount of the reactive species that are produced, and the stripping rate of the resist, provided that there is a sufficiently high flow rate of the process gas from which the reactive species are produced. Microwaves, represented by arrow 38, are produced by the microwave generator 34 and propagated through a waveguide 40 into the passage 32.

The gas source 36 supplies process gas, represented by arrow 42, into the passage 32, where the gas is energized by the microwaves 38 to produce plasma. Gas containing reactive species passes through an opening 44 into the interior of the resist stripping chamber 10.

The reactive species are distributed in the resist stripping chamber 10 by the baffle 50 before flowing onto the substrate 22 and stripping the resist. The substrate 22 is preferably heated by a heater in the substrate support 20, at least prior to stripping the resist. Waste products generated during resist stripping are pumped out of the resist stripping chamber 10 through the exhaust ports 18.

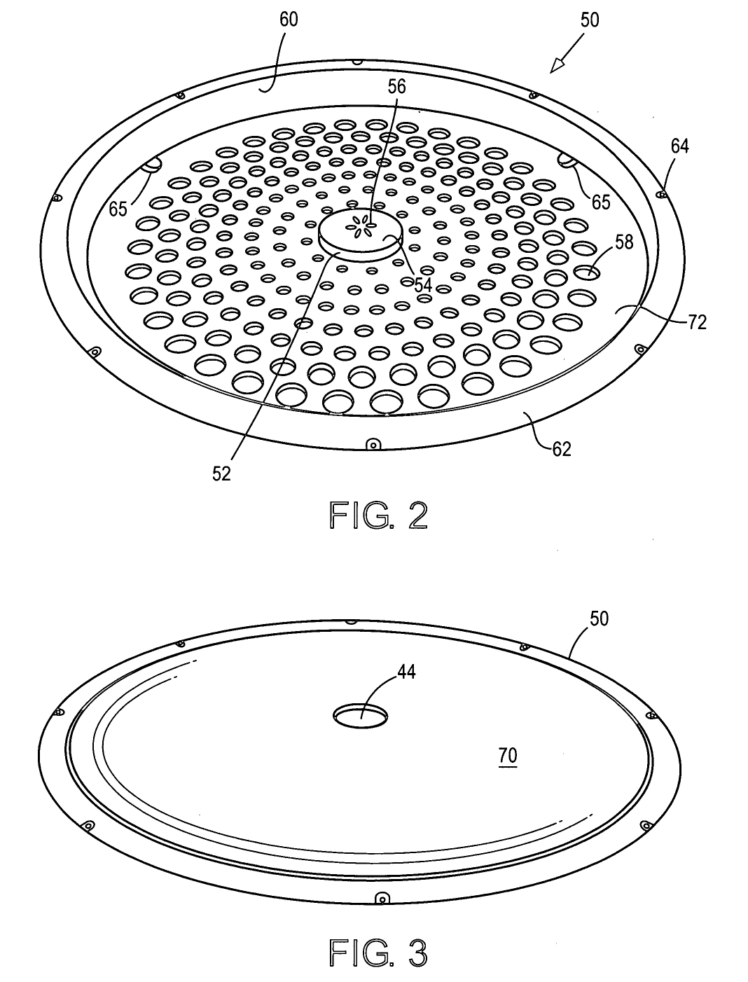

As shown in FIG. 2, the baffle 50 is preferably a circular, one-piece body of a thermally conductive material. The resist stripping chamber 10 is preferably cylindrical for single wafer processing. The baffle 50 includes an inner portion having a raised central portion 52 with an upper surface 54 and through flow passages 56. In the embodiment, UV radiation that passes through the passage 32 impinges on the upper surface 54 in a direction generally perpendicular to the upper surface. The passages 56 are preferably oriented relative to the upper surface 54 to prevent a direct line of sight for UV radiation to pass through the baffle 50 and damage the substrate 22.

The baffle 50 includes through flow passages 58 between the central portion 52 and a peripheral portion 60. The flow passages 58 are configured to distribute reactive species in a desired flow pattern into region of the resist stripping chamber 10 between the baffle 50 and the wafer 22. As shown in FIG. 2, the flow passages 58 preferably are in the form of concentrically-arranged rows of holes. The passages 58 preferably have a round cross section and preferably increase in cross-sectional size (e.g., diameter) in the radial outward direction of the baffle 50 from the central portion 52 toward the peripheral portion 60.

As shown in FIG. 2, the peripheral portion 60 of the baffle 50 includes a flange 62 having holes 64 for receiving fasteners 66 (FIG. 1), to removably attach the baffle 50 to the top surface 68 of the side wall 12 of the resist stripping chamber 10.

A liner 70 can be supported on the upper surface 72 of the baffle 50 to minimize the deposition of materials on the bottom surface of the cover 16 during resist stripping processes. Spacers 65 are provided on the upper surface 72 of the baffle 50 to support the liner 70 and form a plenum 74 therebetween (FIG. 1). The liner 70 includes a centrally-located passage 44 through which reactive species pass from the passage 32 into the plenum 74. The liner 70 is preferably made of aluminum.

The baffle 50 is thermally-grounded, i.e., the baffle 50 is in thermal contact with a portion of the resist stripping chamber 10. For example, when the baffle 50 is adapted to be installed in a cylindrical resist stripping chamber 10, the baffle 50 preferably has a diameter substantially equal to, or larger than, the diameter of the interior of the resist stripping chamber 10, so that the baffle is in direct thermal contact with the side wall 12. The sidewall 12 preferably has a sufficient thermal mass to enhance the rate of heat transfer from the baffle 50 to the sidewall 12.

In a preferred embodiment, the sidewall 12 can be actively temperature controlled. For example, a heat transfer medium, e.g., water or the like, at ambient temperature or lower, can be flowed through the sidewall 12 to cool the sidewall to the desired temperature. The sidewall 12 can typically be cooled to a temperature in the range of from about 20° C. to about 35° C. during resist stripping processes. The sidewall 12 can be cooled when the resist stripping chamber 10 is idle and also during resist stripping processes to maintain the temperature of the baffle 50 at a substantially constant temperature. The baffle 50 is preferably maintained at approximately the temperature of the sidewall 12.

It has been determined, however, that even without actively cooling the sidewall 12, in the resist stripping chamber 10, the baffle 50 can remain at a sufficiently low temperature during resist stripping processes to cool the reactive species sufficiently to avoid detrimental property changes to low-k dielectric materials that can otherwise be damaged by exposure to temperatures above about 100° C., for example.

The baffle 50 preferably has a gas contact surface area that is sufficiently high to allow for the reactive species leaving the plasma source area 30 to thermally equilibrate with the baffle 50 before the reactive species reach the processed surface of the substrate 22. For example, constituents of the remote plasma typically are introduced into the resist stripping chamber at a temperature of from about 125° C. to about 225° C., depending on the power level applied to the process gas by the energy source 34 to produce the remote plasma. It has been determined that the reactive species temperature can be reduced to about the temperature of the baffle 50 (e.g., about 20° C. to about 35° C.) by passing the hot reactive species through the baffle. As a result, heating of the substrate 22 by the reactive species can be minimized, which allows for close control of the substrate temperature.

In a preferred embodiment, variation in process results, substrate-to-substrate and/or or tool-to-tool, is minimized by controlling the reactive species temperature, which is a significant process factor. Close control of the reactive species temperature can significantly reduce first substrate effects (i.e., the first substrate processed during consecutive processing of a batch of wafers) that can result from variations in resist stripping chamber temperatures in non-steady state operation.

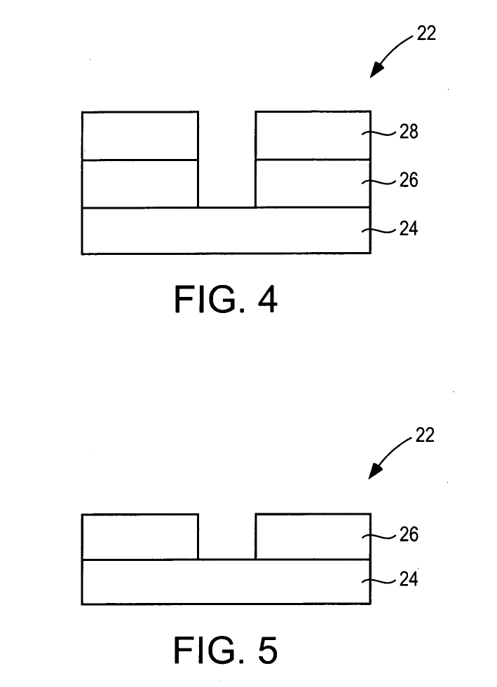

An exemplary embodiment of a substrate 22 that can be processed in the resist strip chamber 10 is shown in FIG. 4. The substrate 22 comprises a base substrate 24, typically of silicon; a layer 26 of a low-k dielectric material, e.g., an organic low-k dielectric material; and an overlying resist layer 28, e.g., an organic single layer or multi-layer resist. The substrate 22 is depicted before resist stripping is performed. In other embodiments, the substrate 22 can include one or more other layers above, below or between the layers shown, depending on the type of electronic device(s) that are built on the substrate 22.

The low-k dielectric material has dielectric properties that undesirably change if the low-k dielectric material layer 26 is heated to a temperature above a thermal degradation temperature of the low-k dielectric material. As used herein, the term “thermal degradation temperature” of a low-k dielectric material is defined as the approximate temperature above which the dielectric properties of the low-k dielectric material detrimentally change. It has been determined that if the dielectric properties of the low-k dielectric material detrimentally change as a result of overheating, then electronic devices built on the substrate 24 have unacceptable performance.

For example, the thermal degradation temperature of certain organic low-k dielectric materials is about 100° C. In the resist stripping process, it is also preferable to remove the resist layer 28 selectively with respect to the low-k dielectric material layer 26. The resist layer 28 is preferably also removed in a minimum amount of time to maximize process efficiency. The etch selectivity is defined by the process gas chemistry used and the temperature of the substrate 22. The removal rate of the resist layer 28 is dependent on the substrate temperature. Accordingly, the preferred condition for resist stripping is to run the process at high power, and with the substrate at a temperature as close as possible to the thermal degradation temperature of the low-k dielectric material of the layer 26, i.e., as close as possible to 100° C. However, by heating the substrate to a temperature close to 100° C. by operation of the heater provided in the substrate support, reactive species at a temperature of above 100° C. can supply sufficient additional energy to raise the wafer temperature above 100° C. It has been determined that by using the thermally-conductive baffle 50, the substrate temperature can be maintained below the thermal degradation temperature of the low-k dielectric material, while the substrate can be heated by a heater to a temperature approaching the thermal degradation temperature.

As the baffle 50 can be maintained at a temperature significantly below 100° C. during resist stripping processes, embodiments of the methods can be used to strip resist from substrates that include a low-k dielectric material, or other material, having a thermal degradation temperature below 100° C., e.g., a temperature between the temperature of the cooled reactive species and 100° C. In the embodiments, the heater in the substrate support 20 can be set to a suitable temperature depending on the thermal degradation temperature that is preferably not to be exceeded.

The process gas used to form the remote plasma includes a mixture of gases. The gas mixture is energized to produce remote plasma. Reactive species from the plasma are supplied into the interior of the resist stripping chamber 10 and are sufficiently long-lived to react with (i.e., reduce, oxidize or “ash”) the resist layer 112 on the substrate 22. The rate at which the resist is removed by the strip process is referred to as the “strip rate.” The process gas can have any suitable composition depending on the substrate composition. For example, the process gas can be an oxygen-containing gas mixture, such as an O₂/H₂/inert gas. The inert gas can be, for example, argon or helium. The gas mixture can also contain a fluorine-containing component, such as CF₄ or C₂F₆. N₂ can be added to the gas mixture to enhance selectivity with respect to the resist material as compared to a second material, such as a barrier and/or underlying material. As used herein, the term “selectivity” with respect to resist material as compared to a second material is defined as the ratio of the resist etch rate to the etch rate of the second material.

During resist stripping, the total flow rate of the process gas is preferably in the range of from about 2000 sccm to about 6000 sccm, and the pressure in the resist stripping chamber 10 is preferably in the range of about 200 mTorr to about 1 Torr. Typical process conditions that can be used for resist stripping processes in the chamber are: an O₂/H₂/CF₄/He process gas mixture, 5000 sccm total process gas flow, at least 2500 W of power applied by the microwave generator, and the heated surface of the substrate support is set to a temperature of from about 80° C. to about 90° C.

### EXAMPLE 1

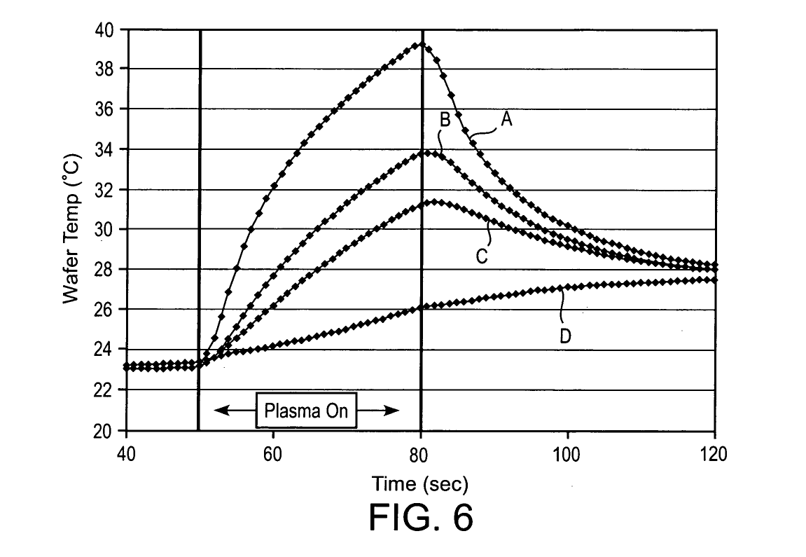

In Example 1, the resist stripping chamber did not include a thermally-grounded, thermally-conductive baffle to cool the reactive species. The temperature of the substrate support was set to 25° C., the chamber pressure was 1 Torr, and a remote plasma was produced by applying a power level of 2500 watts to a gas with a microwave generator for 30 seconds. Temperatures at multiple locations of the surface of the substrate were measured using thermocouples. As shown in FIG. 6, these locations included the center (curve A), the middle (curves B, C), and the edge (curve D) of the substrate surface. As shown, the surface temperature increased by about 16° C. at the center of the substrate surface during the time period that the plasma was on.

### EXAMPLE 2

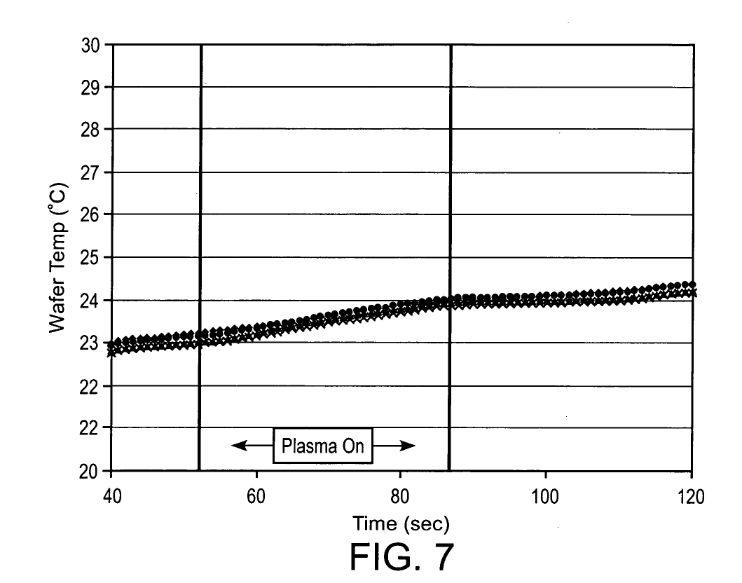

In Example 2, the resist stripping chamber included a thermally-grounded, thermally-conductive baffle mounted to the sidewall above the substrate support. The temperature of the substrate support was set to 25° C., the chamber pressure was at 1 Torr, and a power level of 2500 W was applied to a gas for 30 seconds by the microwave generator. Temperatures at multiple locations of the surface of the substrate were measured using thermocouples. As shown in FIG. 7, the surface remained at a substantially constant temperature of between about 22° C. to about 25° C. at center, middle and edge locations during the time period that the plasma was ignited. The test results demonstrated that the substrate temperature was minimally affected by the reactive species.

### EXAMPLE 3

In Example 3, the resist stripping chamber included a thermally-grounded, thermally-conductive baffle mounted to the sidewall. The temperature of the substrate support was set to 90° C. A power level of 2500 W was applied to the microwave generator during the processing of one substrate. No power was applied to the microwave generator during processing of a second substrate, i.e., no plasma was produced. Both substrates were processed for 10 minutes. Temperatures were measured at the center and edge of the substrate surface. For the substrate processed without plasma generation, the maximum measured temperatures at the center and edge were from 82° C. to 88° C. For the substrate processed with plasma, the maximum measured temperatures at the center and edge were from 88° C. to 93° C. The test results demonstrated that the substrate temperature was minimally affected by the large difference in the temperatures of the gases introduced into the chamber for the two substrates when a thermally-grounded, thermally-conductive baffle was used.

The present invention has been described with reference to preferred embodiments. However, it will be readily apparent to those skilled in the art that it is possible to embody the invention in specific forms other than as described above without departing from the spirit of the invention. The preferred embodiment is illustrative and should not be considered restrictive in any way. The scope of the invention is given by the appended claims, rather than the preceding description, and all variations and equivalents which fall within the range of the claims are intended to be embraced therein.

What is claimed is:

1. A method of stripping resist from a semiconductor substrate in a resist stripping chamber, comprising:
providing a semiconductor substrate in a resist stripping chamber, the semiconductor substrate including a low-k dielectric material and a resist layer overlying the low-k dielectric material, the low-k dielectric material having a thermal degradation temperature;
producing a remote plasma from a process gas and supplying therefrom a gas containing reactive species at a temperature above the thermal degradation temperature of the low-k dielectric material into the resist stripping chamber;
cooling the reactive species in the plasma stripping chamber to a temperature below the thermal degradation temperature of the dielectric material; and
stripping the resist layer from the semiconductor substrate with the cooled reactive species such that the semiconductor substrate does not exceed the thermal degradation temperature of the low-k dielectric material.

2. The method of claim 1, wherein the cooling comprises passing the reactive species through flow passages of a thermally-conductive gas distribution member facing the semiconductor substrate.

3. The method of claim 2, wherein the gas distribution member is of aluminum and has an outer aluminum oxide layer.

4. The method of claim 2, wherein the gas distribution member thermally contacts a portion of the resist stripping chamber that is at a temperature below the thermal degradation temperature of the low-k dielectric material.

5. The method of claim 4, wherein the gas distribution member and the portion of the resist stripping chamber are at approximately the same temperature during the resist stripping.

6. The method of claim 4, wherein the portion of the resist stripping chamber is actively cooled.

7. The method of claim 1, wherein the semiconductor substrate is supported on a support surface of a substrate support, the substrate support includes a heater which heats the support surface to a temperature below the thermal degradation temperature of the low-k dielectric material.

8. The method of claim 1, wherein the remote plasma is produced by applying power to the process gas using a microwave energy source.

9. The method of claim 8, wherein the low-k dielectric material is an organic low-k dielectric material.

10. The method of claim 1, comprising consecutively processing a plurality of the semiconductor substrates in the resist stripping chamber such that each of the semiconductor substrates is maintained at a temperature that does not exceed the thermal degradation temperature of the low-k dielectric material during the stripping of the resist layer.

11. The method of claim 1, wherein the process gas comprises oxygen, hydrogen and fluorine.

12. A method of stripping resist from a semiconductor substrate in a resist stripping chamber, comprising:
providing a semiconductor substrate in a resist stripping chamber, the semiconductor substrate including an organic low-k dielectric material and a resist layer overlying the low-k dielectric material, the low-k dielectric material having a thermal degradation temperature;
producing a remote plasma from a process gas and supplying therefrom a gas containing reactive species at a temperature above the thermal degradation temperature of the low-k dielectric material into the resist stripping chamber;
passing the reactive species through flow passages of a thermally-conductive gas distribution member facing the semiconductor substrate, thereby cooling the reactive species to a temperature below the thermal degradation temperature of the low-k dielectric material; and
stripping the resist layer from the semiconductor substrate with the cooled reactive species such that the semiconductor substrate does not exceed the thermal degradation temperature of the low-k dielectric material.

13. The method of claim 12, wherein the gas distribution member thermally contacts a wall of the resist stripping chamber that is at a temperature below the thermal degradation temperature of the low-k dielectric material.

14. The method of claim 13, wherein the gas distribution member and the wall are at approximately the same temperature during the resist stripping.

15. The method of claim 13, comprising actively cooling the wall.

16. The method of claim 12, wherein the semiconductor substrate is supported on a support surface of a substrate support, the substrate support includes a heater which heats the support surface to a temperature below the thermal degradation temperature of the low-k dielectric material.

17. The method of claim 16, wherein:
the thermal degradation temperature of the low-k dielectric material is about 100° C.; and
the support surface is heated to a temperature of from about 25° C. to about 95° C. by the heater.

18. The method of claim 17, wherein the reactive species are supplied into the resist stripping chamber at a temperature of up to about 225° C. prior to passing through the gas distribution member.

19. The method of claim 12, wherein:
the thermal degradation temperature of the low-k dielectric material is about 100° C.; and
the reactive species are supplied into the resist stripping chamber at a temperature of up to about 225° C. prior to passing through the gas distribution member.

20. The method of claim 12, wherein the chamber wall is cooled to a temperature of from about 20° C. to about 35° C. during the resist stripping.

21. The method of claim 12, wherein the remote plasma is produced by applying microwave energy to the process gas at a power level of from about 2000 W to about 3000 W.

22. The method of claim 12, comprising consecutively processing a plurality of the semiconductor substrates in the resist stripping chamber such that each of the semiconductor substrates is maintained at a temperature that does not exceed the thermal degradation temperature of the low-k dielectric material during the stripping of the resist layer.

23. The method of claim 12, wherein the process gas comprises oxygen, hydrogen and fluorine.

24. A method of stripping resist from a semiconductor substrate in a resist stripping chamber, comprising:
supporting a semiconductor substrate on a support surface in a resist stripping chamber, the semiconductor substrate including a resist layer overlying an organic low-k dielectric material having a thermal degradation temperature;
heating the support surface to a temperature below the thermal degradation temperature of the low-k dielectric material;
applying energy to a process gas using a microwave energy source to produce a remote plasma and supplying reactive species therefrom at a temperature above the thermal degradation temperature of the low-k dielectric material into the resist stripping chamber;
cooling the reactive species to a temperature below the thermal degradation temperature of the low-k dielectric material inside the resist stripping chamber; and
removing the resist layer from the semiconductor substrate with the cooled reactive species such that the semiconductor substrate does not exceed the thermal degradation temperature of the low-k dielectric material.

25. The method of claim 24, comprising consecutively processing a plurality of the semiconductor substrates in the resist stripping chamber such that each of the semiconductor substrates is maintained at a temperature that does not exceed the thermal degradation temperature of the low-k dielectric material during the stripping of the resist layer.

26. The method of claim 24, wherein the process gas comprises oxygen, hydrogen and fluorine.
